(19) United States
(12) Patent Application Publication
(10) Pub. No.: US 2004/0229412 A1
(43) Pub. Date: Nov. 18, 2004

(54) Inverter made of complementary p and n channel transistors using a single directly-deposited microcrystalline silicon film

(76) Inventors: Sigurd Wagner, Princeton, NJ (US); Yu Chen, Pearland, TX (US)

Correspondence Address: Wolff & Samson PC, One Boland Drive, West Orange, NJ, 07052, US

(21) Appl. No.: 10/746,945

(22) Filed: Dec. 24, 2003

Related U.S. Application Data
(63) Continuation-in-part of application No. 10/030,371, filed on Mar. 6, 2002, now Pat. No. 6,713,329.
Application No. 10/030,371 is a 371 of international application No. PCT/US00/12762, filed on May 10, 2000.
(60) Provisional application No. 60/133,372, filed on May 10, 1999.

(51) Int. Cl. H01L 21/00; H01L 21/84

(52) U.S. Cl. 438/154

(57) ABSTRACT

A p channel thin-film transistor (TFT) made of directly deposited microcrystalline silicon (μc-Si). The p TFT is integrated with its n channel counterpart on a single μc-Si film, to form a complementary metal-silicon oxide-silicon (CMOS) inverter of deposited μc-Si. The μc-Si channel material can be grown at lower temperatures by plasma-enhanced chemical vapor deposition in a process similar to the deposition of hydrogenated amorphous silicon. The p and n channels share the same μc-Si layer.

### RELATED APPLICATIONS

This application is a continuation-in-part of U.S. patent application Ser. No. 10/030,371 filed Mar. 6, 2002, now U.S. Pat. No. ______ issued ______, which application is a U.S. national phase application under 35 U.S.C. § 371 of PCT Application Serial No. PCT/US00/12762 filed May 10, 2000, which claims the benefit of U.S. Provisional Application Ser. No. 60/133,372 filed May 10, 1999. The disclosures of each of these applications are expressly incorporated herein by reference.

### GOVERNMENT RIGHTS

The present invention has been made under a contract by the New Jersey Commission of Science and Technology and DARPA and the government may have certain rights to the subject invention.

### BACKGROUND OF THE INVENTION

1. Field of the Invention

This invention generally relates to the fabrication of large area electronic products, and more specifically to the fabrication of complementary metal-oxide semiconductor (CMOS) circuits for large-area macroelectronics and add-on electronics for application-specific integrated circuits (ASICs), at low temperatures by directly depositing microcrystalline thin-film silicon (μC-Si).

2. Related Art

It is known how to make CMOS circuits at temperatures in excess of 600° C., which is the lowest temperature at which polycrystalline films can be made by thermal crystallization. These films are then processed to CMOS circuits.

An ultralow-temperature, large-area silicon technology that could furnish a tool kit of standard devices, including transistors, rectifying diodes and photodiodes is of great interest for applications in macroelectronics, and in add-on electronics for application-specific integrated circuits. The latter application requires that all process temperatures lie below 400° C., and in general a reduction of the process temperature expands the applicability of macroelectronics. A widely usable ultralow-temperature technology needs p channel and n channel field-effect transistors (FETs), which are the building blocks for complementary digital circuits. n channel FETs made of directly deposited microcrystalline silicon (μc-Si) indeed have been reported by: T. Nagahara, K. Fujimoto, N. Kohno, Y. Kashiwagi and H. Kakinoki, Jpn. J. Appl. Phys. 31, 4555 (1992); J. Woo, H. Lim and J. Jang, Appl. Phys. Lett. 65, 1644 (1994); H. Meiling, A. M. Brockhoff, J. K. Rath and R. E. I. Schropp, Mat. Res. Soc. Symp. Proc. 508, 31 (1998); and Y. Chen and S. Wagner, Electrochem. Soc. Proc. 98-22, 221 (1998). The fabrication of solar cells of μc-Si suggests that useful hole mobilities can be obtained in μc-Si. However, no p channel thin film transistors (TFTs) have been made of hydrogenated amorphous silicon (a-Si:H), which is an efficient solar cell material.

What would be desirable, but has not heretofore been developed, is a method of fabricating macroelectronic devices and ASICs at low temperatures by directly depositing μc-Si and integrating a p channel TFT with an n channel TFT to form an inverter. An inverter is a basic logic circuit. The ability to fabricate an inverter of μc-Si demonstrates the usability of μc-Si for the fabrication of logic circuits.

### OBJECTS AND SUMMARY OF THE INVENTION

It is a primary object of the present invention to provide a method of making large area electronic devices at low temperatures.

It is another object of the present invention to provide a method of making CMOS circuits at low temperatures.

It is another object of the present invention to provide a method of making TFTs by directly depositing μc-Si.

It is an additional object of the present invention to provide a method of integrating p channel and n channel TFTs to form an inverter.

It is even a further object of the present invention to provide a method for making p channel and n channel transistors from the same film of μc-Si.

It is even an additional object of the present invention to provide a TFT wherein the p and n channels share a single μc-Si layer.

A p channel TFT is made of directly deposited microcrystalline silicon (μc-Si). The p TFT is integrated with its n channel counterpart on a single μc-Si film, to form a complementary metal-silicon oxide-silicon (CMOS) inverter of deposited μc-Si. The μc-Si channel material can be grown at low temperatures by plasma-enhanced chemical vapor deposition in a process similar to the deposition of hydrogenated amorphous silicon. Either the p⁺ or n⁺ layers can be grown and patterned, and then the other can be deposited and patterned. The p and n channels share the same μc-Si layer.

### BRIEF DESCRIPTION OF THE DRAWINGS

Other important objects and features of the invention will be apparent from the following Detailed Description of the Invention taken in connection with the accompanying drawings in which:

FIGS. 1A-1F are schematic views of the process sequence for the microcrystalline silicon CMOS inverter according to the present invention.

FIGS. 2A and 2B show the transfer characteristics of the (a) p channel μc-Si TFT, and (b) n channel μc-Si TFT of the CMOS inverter according to FIG. 1.

FIG. 3 shows the voltage transfer characteristics of a CMOS inverter made of μc-Si according to FIG. 1. The p channel and n channel TFTs have identical channel dimensions. V_{DD}=30 V and V_{SS}=−20 V.

### DETAILED DESCRIPTION OF THE INVENTION

The present invention relates to ultralow-temperature semiconductor technology based on directly deposited μc-Si. One aspect of the invention is the successful fabrication of p channel thin-film transistors deposited at 320° C. and processed at a maximum temperature of 280° C. Another aspect of the invention is the integration of this p channel TFT with an n channel TFT to an inverter to create a complementary metal-oxide-silicon (CMOS) circuit made of microcrystalline silicon.

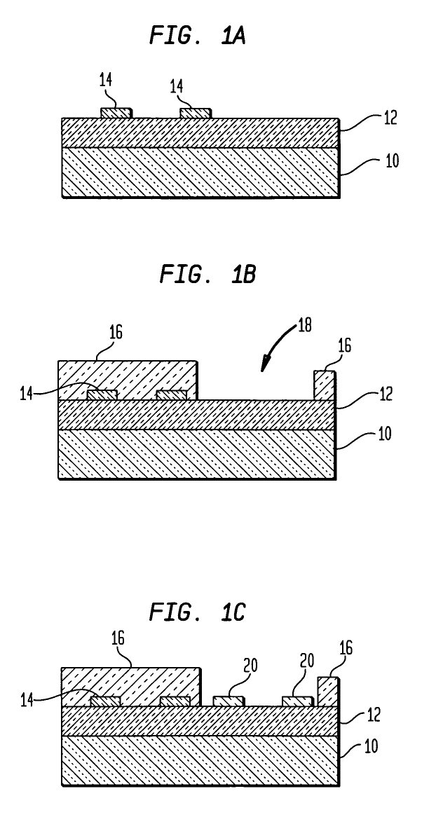

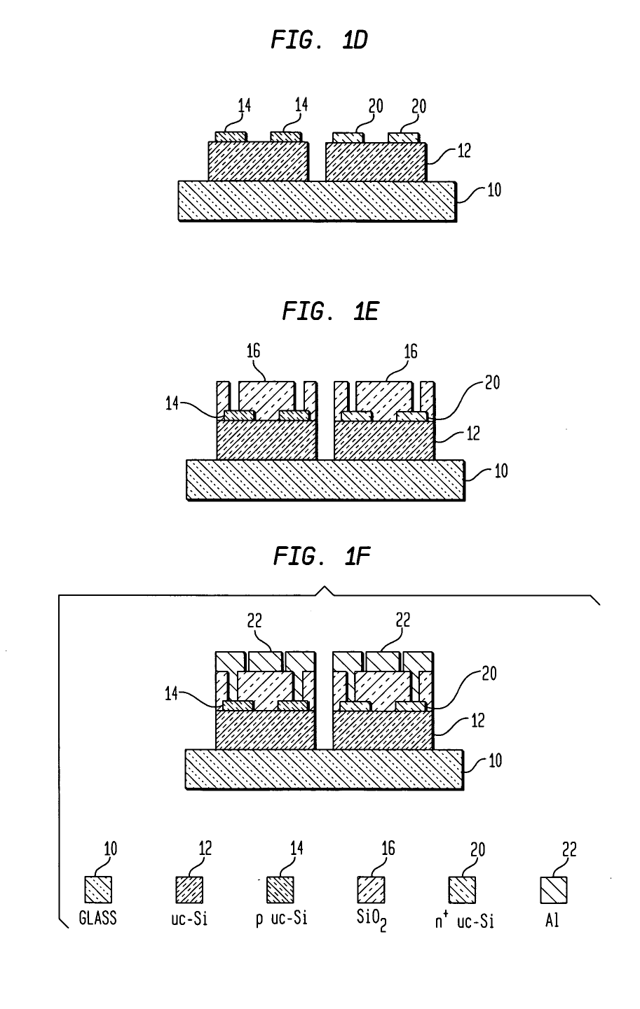

The μc-Si CMOS process of the present invention is described with reference to FIG. 1. Both the p type and the n type TFT use one single directly deposited μc-Si layer 12 as the conducting channel. The μc-Si channel material 12 can be grown by plasma-enhanced chemical vapor deposition (PECVD) in a process similar to the deposition of a-Si:H. The undoped channel and the p⁺ and n⁺ contact layers, 14 and 20 respectively, can be grown by PECVD. The SiO₂ gate dielectric 16 can also be grown by PECVD. Corning 7059 glass can be used as the substrate 10. The channel layers of undoped i μc-Si can be grown by DC excitation of a mixture of SiH₄, SiF₄ and H₂. Adding SiF₄ to the source gas provides a large deposition space than deposition from H₂-diluted SiH₄ alone. The growth rate was 0.6 Å/s at a power density of 160 mW/cm². The dark conductivity of the i μc-Si is 1×10⁻⁷ S/cm, and its thermal activation energy is 0.55 eV. The p⁺ and n² source/drain contact layers were grown from SiH₄, H₂, and B₂H₆ or PH₃ by RF excitation at 13.56 MHz. Their dark conductivities are 0.01 S/cm (p⁺ μc-Si) and 20 S/cm (n⁺ μc-Si). Growth parameters are listed in Table 1.

TABLE 1
Deposition parameters for the undoped microcrystalline silicon of the TFT
channels, the dopes source/drain contact layers, and the SiO₂ used for isolation.

| | | | | PH₃, | | Power | | |
|---|---|---|---|---|---|---|---|---|
| | | | | B₂H₆, | | density | | Film |
| | SiH₄ | H₂ | SiF₄ | or N₂O | Temp. | (mW/ | Pressure | 6thickness |
| Layer | (sccm) | (sccm) | (sccm) | (sccm) | (° C.) | cm²) | (mTorr) | (nm) |
| μc-Si | 1 | 200 | 20 | 0 | 360 | 160 | 900 | 300 |
| p⁺ μc-Si | 2 | 100 | 0 | 50 | 280 | 324 | 900 | 60 |
| n⁺ μc-Si | 2 | 100 | 0 | 12 | 280 | 324 | 900 | 60 |
| SiO₂ | 35 | 0 | 0 | 160 | 250 | 85 | 400 | 200 |

The TFTs were made in the top-gate configuration shown in FIGS. 1A-1F. The CMOS inverter is made of a p channel TFT and an n channel TFT of identical structure. A six-level mask process with specially designed masks was used in the inverter fabrication. First, 300 nm of i μc-Si and 60 nm of p⁺ μc-Si layer 12 were grown on the substrate 10 without breaking vacuum. Next, as shown in FIG. 1A, the p⁺ μc-Si source and drain for the p channel TFT 14 were patterned using reactive ion etching (RIE) with 10% O₂ and 90% CCl₂F₂. As shown in FIG. 1B, the deposition of a layer of 200 nm isolation SiO₂ 16 followed. Referring to 16, a window 18 in the SiO₂ was opened using buffered oxide etch (BOE) to deposit a 60 nm n⁺ μc-Si layer. After RIE patterning of the n⁺ μc-Si source and drain for the n channel TFT 20, the SiO₂ layer was removed with BOE (FIG. 1D), and followed by the definition of the i μc-Si island using RIE. Then, as shown in FIG. 1E, 200 nm SiO₂ 16 was deposited as gate insulator, and the SiO₂ gate was patterned and contact holes opened to the n and p channel TFT source and drain using BOE. Then, as shown in FIG. 1F, Al 22 was thermally evaporated and patterned using a wet-etch to form the gate, source and drain electrodes of the n and p channel TFTs, as well as the metal interconnects between the two gates, and the p TFT drain in the n TFT source. Other metals or alloys, such as Al, Cr, Cu, Ti, Mo, or Ta, and their alloys could be used to form the electrodes. The pull-up p channel TFT and pull-down n channel TFT have 180-μm long channels. These large dimensions result from use of a laser printer for the fabrication of the photolithographic mask.

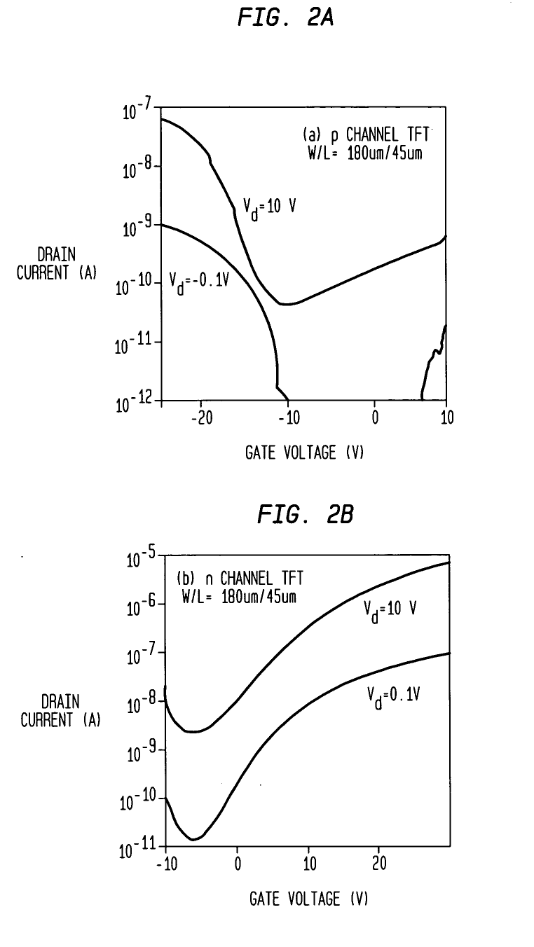

FIG. 2 shows the transfer characteristics of the p channel and n channel TFTs of the inverter. The ON current I_{ON} is defined as the drain current I_{d} at a gate voltage V_{gs} of (− or +) 25 V, and the OFF current I_{OFF} as the lowest drain current, both at a drain voltage of V_{ds} of (− or +) 10 V. FIG. 2A shows a p channel TFT ON/OFF current ration of >10³, a threshold voltage V_{TH} of −16 V, and a subthreshold slope S of 2.7 V/dec. The hole field-effect mobilities μₕ of the p channel TFT extracted from the linear and saturated regimes are 0.023 and 0.031 cm²/Vs, respectively. The ON/OFF current ration of the n channel TFT of FIG. 2B is ˜10⁴, its V_{TH} is 3 V, and S=4.2 V/dec. The electron field-effect mobilities μₙ of the n channel TFT extracted from the linear and saturated regimes are 0.72 and 1.0 cm²/Vs, respectively. These μₙ values lie substantially below those obtained in a separately fabricated μc-Si n channel TFT. We ascribe the reduction in field-effect mobility to the unoptimized process sequence for CMOS inverter fabrication, which also is reflected in the values for VTH and S.

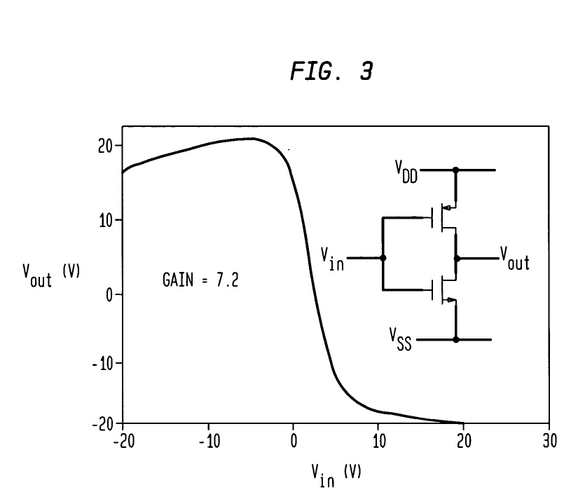

The voltage transfer characteristic of the CMOS inverter made of the pull-up p channel TFT and the pull-down n channel TFT is shown in FIG. 3 for supply voltages of V_{dd}=30 V and Vₛₛ=−20 V. The inverter exhibits a nearly full rail-to-rail swing, and an abrupt and well-defined voltage transfer characteristic with a gain of 7.2. The output HIGH is about 90% of the full voltage range and the output LOW is at the same voltage as Vₛₛ.

Thus, the present invention introduces a new digital device and circuit technology based on directly deposited microcrystalline thin-film silicon. Its maximum process temperature of 320° C. is ideally suited to glass substrates, and of course is suitable to more refractory substrates such as steel. The process temperature can be reduced to make the process compatible with a large number of organic polymer substrates. The invention also is suited as a complementary metal-oxide-silicon (CMOS) technology for add-on circuits to application-specific integrated circuits (ASICS).

A number of substrates, such as glass, metal, steel, and polymers including organic and silicone polymers can be utilized as substrates for the present invention. Glass can be used directly, or it can be coated with a buffer layer that functions as a barrier against diffusion of impurities from the glass into subsequent transistor layers. Such coating can be applied to one or both sides of the glass substrate. An example of a suitable buffer layer is a 1 μm thick silicone dioxide (SiO₂) layer deposited on the substrate by any desired process, such as spin-on of a silica sol followed by baking, chemical vapor deposition (CVD), plasma-enhanced chemical vapor deposition (PE-CVD), sputtering, electron beam evaporation, or any other suitable process. The substrate can then be coated with an organic polymer or silicone polymer to reduce glass breakage, which coating can also be applied to one or both sides of the substrate.

If a metal (e.g., steel) substrate is provided, the substrate is coated with a buffer layer that functions as a barrier against diffusion of impurities from the substrate into subsequent transistor layers, planarizes the roughness of the substrate, and acts as an electrical insulator. An example of a suitable buffer layer is a 0.5 μm thick silica layer deposited by spin-on of silica sol followed by baking, which layer can later be doped with a diffusion retardant such as phosophorus. An organic polymer layer can also be deposited by spin-on of a monomer followed by curing to a polymer, e.g., a polyimide. Such coatings can be applied to one side of the metal substrate, or to both sides. A high-purity electrical insulator can then be formed on the substrate, such as a 0.5 μm thick SiO₂ layer deposited by CVD, PE-CVD, sputtering, electron beam evaporation, or any other suitable process. The insulator can be applied to one or both sides of the substrate.

Substrates comprising organic or silicone polymers can also be provided. In the case of an organic polymer substrate, such as a polyimide (e.g., KAPTON E manufactured by DUPONT), a polycarbonate (e.g., LEXAN manufactured by GENERAL ELECTRIC), a polyethylene teraphthalate (PET), or a polyester such as PEN, the polymer is coated with a multi-functional passivation layer. The passivation layer prevents degassing of the polymer during device fabrication, protects the polymer from process chemicals used during the formation of the device, and bonds the device layers to the polymer substrate. Examples of the passivation layer include a 0.5 μm thick SiO₂ layer deposited by PE-CVD or other suitable process, and a 0.5 μm thick layer of SiNₓ deposited by PE-CVD or other suitable process. The passivation layer can be applied to one or both sides of the substrate.

In the case of a silicone polymer substrate such as poly dimethyl siloxane (PDMS), the substrate can be coated with the same passivation layer utilized with organic polymer substrates and described above. Patterned islands can be formed in the passivation layer, which islands function as platforms for transistor circuits. In this arrangement, the polymer substrate areas between the islands are not coated, so that such areas can be deformed without breaking the islands. The passivation layer and islands can be formed on one or both sides of the substrate.

Having thus described the invention in detail, it is to be understood that the foregoing description is not intended to limit the spirit and scope thereof. What is desired to be protected by Letters Patent is set forth in the appended claims.

What is claimed is:

1. A method of manufacturing a CMOS inverter comprising:
providing a glass substrate;
coating the glass substrate with a buffer layer;
forming a microcrystalline silicon (μc-Si) layer on the buffer layer; and
forming p and n type TFTs on the microcrystalline layer.

2. The method of claim 1, further comprising coating the buffer layer with a polymer layer for reducing breakage of the substrate.

3. The method of claim 2, wherein the step of coating the buffer layer with a polymer layer comprises coating the buffer layer with an organic polymer or a silicone polymer.

4. The method of claim 1, further comprising coating the glass substrate with a layer of SiO₂ to form the buffer layer.

5. The method of claim 4, further comprising applying the layer of SiO₂ on the substrate using a spin-on of a silica sol followed by baking.

6. The method of claim 5, further comprising depositing the layer of SiO₂ on the substrate using chemical vapor deposition (CVD), plasma-enhanced chemical vapor deposition (PE-CVD), or sputtering.

7. A complementary metal-silicon oxide-silicon (CMOS) inverter comprising:
a glass substrate;
a buffer layer on the substrate;
a microcrystalline silicon (μc-Si) layer on the buffer layer;
a p channel thin film transistor (TFT) on the μc-Si layer;
an n channel TFT on the μc-Si layer;
a patterned gate insulator on the n and p channel TFTs; and
metal gate source and drain electrodes interconnected with the n and p channel TFTs.

8. The inverter of claim 7, further comprising a polymer layer on the buffer layer for reducing glass breakage.

9. The inverter of claim 8, wherein the polymer layer comprises an organic polymer or a silicone polymer.

10. The inverter of claim 7, wherein the buffer layer comprises a layer of SiO₂.

11. The inverter of claim 7, wherein the metal gate source and drain electrodes are made from one or more of the group comprising Al, Cr, Cu, Ti, Mo, Ta and their alloys.

12. The inverter of claim 7, further comprising an island in the μc-Si layer separating the n and p channel TFTs.

13. A method of manufacturing a CMOS inverter comprising:
providing a metal substrate;
growing i μc-Si layer on the substrate;
growing and patterning one of a p⁺ or n⁺ μc-Si on the i μc-Si layer;
depositing and patterning the other of an n⁺ or p⁺ μc-Si on the i μc-Si layer;
depositing SiO₂ as a gate insulator;
patterning the SiO₂ gate;
opening contact holes in n and p channel TFT source and drain; and
evaporating and patterning metal to form gate source and drain electrodes of the n and p channel TFTs and metal interconnects between the gates.

14. The method of claim 13, further comprising coating the metal substrate with a buffer layer to prevent diffusion of impurities from the metal substrate, the buffer layer planarizing roughness of the metal substrate and acting as an electrical insulator.

15. The method of claim 13, further comprising coating the metal substrate with a layer of silica sol and baking the silica sol to form the buffer layer.

16. The method of claim 15, further comprising doping a diffusion retardant into the silica sol layer.

17. The method of claim 13, further comprising coating the metal substrate with a monomer and curing the monomer to form a polymeric buffer layer.

18. The method of claim 13, further comprising coating the buffer layer with a high-purity electrical insulator.

19. The method of claim 18, further comprising depositing a layer of SiO₂ on the substrate to form the insulator using chemical vapor deposition (CVD), plasma-enhanced chemical vapor deposition (PE-CVD), sputtering, or electron beam evaporation.

20. A complementary metal-silicon oxide-silicon (CMOS) inverter comprising:
a metal substrate;
a microcrystalline silicon (μc-Si) layer on the substrate;
a p channel thin film transistor (TFT) on the μc-Si layer;
an n channel TFT on the μc-Si layer;
a patterned gate insulator on the n and p channel TFTs; and
metal gate source and drain electrodes interconnected with the n and p channel TFTs.

21. The inverter of claim 20, further comprising a buffer layer on the metal substrate for preventing diffusion of impurities from the metal substrate, the buffer layer planarizing roughness of the metal substrate and acting as an electrical insulator.

22. The inverter of claim 21, wherein the buffer layer comprises silica sol doped with a diffusion retardant.

23. The inverter of claim 21, wherein the buffer layer comprises a polymeric buffer layer.

24. The inverter of claim 21, further comprising a high-purity electrical insulator on the buffer layer.

25. The inverter of claim 24, wherein the insulator comprises a layer of SiO₂.

26. The inverter of claim 20, wherein the metal gate source and drain electrodes are made from one or more of the group comprising Al, Cr, Cu, Ti, Mo, Ta and their alloys.

27. The inverter of claim 20, further comprising an island in the μc-Si layer separating the n and p channel TFTs.

28. A method of manufacturing a CMOS inverter comprising:
providing a polymer substrate;
growing i μc-Si layer on the substrate;
growing and patterning one of a p⁺ or n⁺ μc-Si on the i μc-Si layer;
depositing and patterning the other of an n⁺ or p⁺ μc-Si on the i μc-Si layer;
depositing SiO₂ as a gate insulator;
patterning the SiO₂ gate;
opening contact holes in n and p channel TFT source and drain; and
evaporating and patterning metal to form gate source and drain electrodes of the n and p channel TFTs and metal interconnects between the gates.

29. The method of claim 28, wherein the step of providing a polymer substrate comprises providing an organic polymer substrate.

30. The method of claim 29, further comprising coating the organic polymer substrate with a passivation layer.

31. The method of claim 30, further comprising depositing a layer of SiO₂ by plasma-enhanced chemical vapor deposition (PE-CVD) on the substrate to form the passivation layer.

32. The method of claim 30, further comprising depositing a layer of SiNₓ by plasma-enhanced chemical vapor deposition (PE-CVD) on the substrate to form the passivation layer.

33. The method of claim 28, wherein the step of providing a non-glass substrate comprises providing a silicone polymer substrate.

34. The method of claim 33, further comprising coating the silicone polymer substrate with a passivation layer.

35. The method of claim 34, further comprising depositing a layer of SiO₂ by plasma-enhanced chemical vapor deposition (PE-CVD) on the substrate to form the passivation layer.

36. The method of claim 34, further comprising depositing a layer of SiNₓ by plasma-enhanced chemical vapor deposition (PE-CVD) on the substrate to form the passivation layer.

37. The method of claim 34, further comprising patterning and etching islands in the passivation layer.

38. A complementary metal-silicon oxide-silicon (CMOS) inverter comprising:
a polymer substrate;
a microcrystalline silicon (μc-Si) layer on the substrate;
a p channel thin film transistor (TFT) on the μc-Si layer;
an n channel TFT on the μc-Si layer;
a patterned gate insulator on the n and p channel TFTs; and
metal gate source and drain electrodes interconnected with the n and p channel TFTs.

39. The method of claim 38, wherein the polymer substrate comprises an organic polymer substrate.

40. The method of claim 39, further comprising a passivation layer on the organic polymer substrate.

41. The method of claim 40, wherein the passivation layer comprises a layer of SiO₂.

42. The method of claim 40, wherein the passivation layer comprises a layer of SiNₓ.

43. The method of claim 38, wherein the polymer substrate comprises a silicone polymer substrate.

44. The method of claim 43, further comprising a passivation layer on the silicone polymer substrate.

45. The method of claim 44, wherein the passivation layer comprises a layer of SiO₂.

46. The method of claim 44, wherein the passivation layer comprises a layer of SiNₓ.

47. The method of claim 44, further comprising islands formed in the passivation layer.

48. The inverter of claim 38, wherein the metal gate source and drain electrodes are made from one or more of the group comprising Al, Cr, Cu, Ti, Mo, Ta and their alloys.

49. The inverter of claim 38, further comprising an island in the μc-Si layer separating the n and p channel TFTs.
